(19) United States
(12) Patent Application Publication
(10) Pub. No.: US 2007/0212844 A1
(43) Pub. Date: Sep. 13, 2007

(54) Method for making a capacitor

(76) Inventor: Chang-Liang Lin, Taoyuan Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/723,041

(22) Filed: Mar. 16, 2007

Related U.S. Application Data
(63) Continuation-in-part of application No. 11/370,026, filed on Mar. 8, 2006, now abandoned.

(51) Int. Cl. H01L 21/20

(52) U.S. Cl. 438/381

(57) ABSTRACT

A method for making a capacitor includes: forming an anode that has a main body and a lead; mounting securely an insulator washer on the lead such that the insulator washer is spaced apart from an upper end of the main body of the anode, the insulator washer dividing the lead of the anode into an upper end portion and a lower end portion; forming a dielectric layer on the main body and the lead of the anode such that the dielectric layer has a main portion covering the main body, and a lead portion covering the lower end portion of the lead of the anode; and forming a conductive layer on the dielectric layer such that the conductive layer covers the main portion of the dielectric layer and the lead portion of the dielectric layer.

### CROSS-REFERENCE TO RELATED APPLICATION

This application is a continuation-in-part (CIP) of U.S. patent application Ser. No. 11/370,026, filed by the applicant on Mar. 8, 2006, and abandoned as of the filing date of this application.

### BACKGROUND OF THE INVENTION

1. Field of the Invention

This invention relates to a method for making a capacitor, more particularly to a method involving formation of a dielectric layer on an anode and a conductive layer on the dielectric layer for making a capacitor.

2. Description of the Related Art

FIGS. 1 and 2 illustrate consecutive steps of a conventional method for making a tantalum capacitor. The conventional method includes the steps of: forming an anode 7 (see FIG. 1), which has a main body 71 and a lead 72, through sintering techniques that use metal powder and a metal rod as materials for forming the main body 71 and the lead 72, respectively; mounting an insulator washer 81 on the lead 72 in such a manner that the insulator washer 81 is in sealing contact with a portion 711 of an outer surface of the main body 71 (see FIG. 1); forming a dielectric layer 82 on the anode 7 by anodizing techniques such that the dielectric layer 82 covers the remainder of the outer surface of the main body 71 (see FIG. 1); forming a conductive layer 83 on the dielectric layer 82 by immersing the anode 7 in a solution 70 of a conductive polymer in such a manner that the surface of the solution 70 of the conductive polymer is substantially flush with an upper surface of the insulator washer 81 (see FIG. 2), followed by drying the film of the conductive polymer adhered to the dielectric layer 82; and forming a cathode (not shown) on the conductive layer 83.

The aforesaid conventional method is disadvantageous in that since the size of the tantalum capacitor is in a relatively small scale and since the insulator washer 81 is relatively thin, an excess film 831 of the conductive polymer (see FIG. 2), which is an extension of the conductive layer 83, is likely to be formed by virtue of the surface tension of the conductive polymer during formation of the conductive layer 83, which undesirably bridges the lead 72 and the conductive layer 83 and which will result in a short circuit during use of the capacitor thus formed. Hence, an additional processing is required to remove the excess film 831 of the conductive polymer, thereby resulting in an increase in the manufacturing costs. Moreover, due to downward creeping of the thin film of the conductive polymer formed on an upper end of the main body 71 of the anode 7 by virtue of gravity during drying process of the film of the conductive polymer and due to a relatively small amount of the conductive polymer retained on the upper end of the main body 71, the corners 712 of the main body 71 tend to be exposed from the conductive layer 83 without the protection of the latter, thereby resulting in an adverse affect on the performance of the capacitor thus formed.

### SUMMARY OF THE INVENTION

Therefore, the object of the present invention is to provide a method for making a capacitor that can overcome the aforesaid drawbacks associated with the prior art.

According to this invention, there is provided a method for making a capacitor that comprises: (a) forming an anode that has a main body and a lead, the main body having an upper end, the lead extending outwardly and being reduced in cross-section from the upper end of the main body; (b) mounting securely an insulator washer on the lead such that the insulator washer is spaced apart from the upper end of the main body of the anode, the insulator washer having a lower surface facing the upper end of the main body of the anode, and an upper surface opposite to the lower surface, and dividing the lead of the anode into an upper end portion that extends upwardly from the upper surface of the insulator washer, and a lower end portion that extends downwardly from the lower surface of the insulator washer to the upper end of the main body; (c) forming a dielectric layer on an outer surface of the main body and an outer surface of the lower end portion of the lead of the anode such that the dielectric layer has a main portion covering the outer surface of the main body, and a lead portion covering at least a portion of the outer surface of the lower end portion of the lead of the anode; (d) forming a conductive layer on the dielectric layer such that the conductive layer covers an outer surface of the main portion of the dielectric layer and at least a portion of an outer surface of the lead portion of the dielectric layer; and (e) forming a cathode on the conductive layer.

### BRIEF DESCRIPTION OF THE DRAWINGS

Other features and advantages of the present invention will become apparent in the following detailed description of the preferred embodiment of this invention, with reference to the accompanying drawings, in which:

FIGS. 1 and 2 are schematic sectional views to illustrate consecutive steps of a conventional method for making a capacitor;

FIG. 3 is a schematic sectional view of a capacitor formed by the preferred embodiment of a method according to this invention; and

FIGS. 4 to 6 are schematic sectional views to illustrate consecutive steps of the preferred embodiment of the method for making the capacitor of FIG. 3.

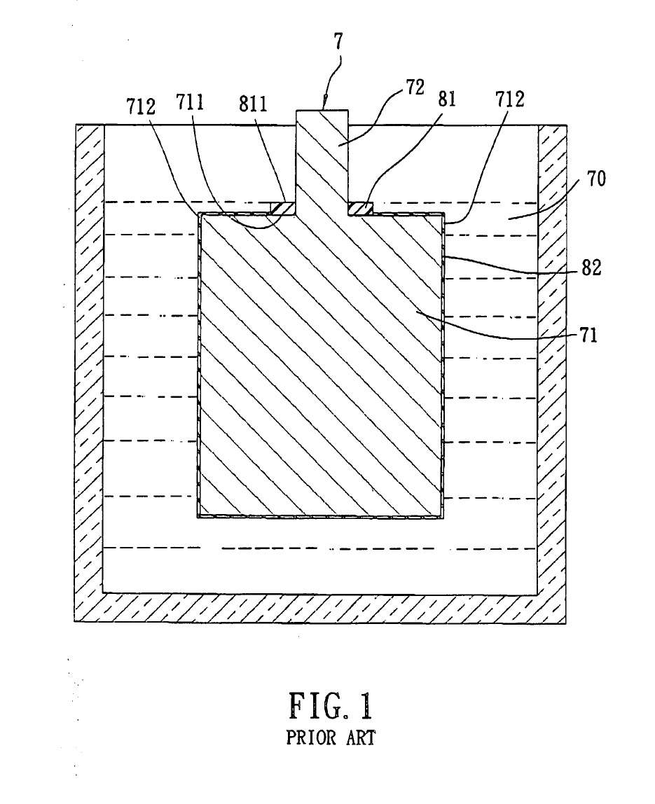

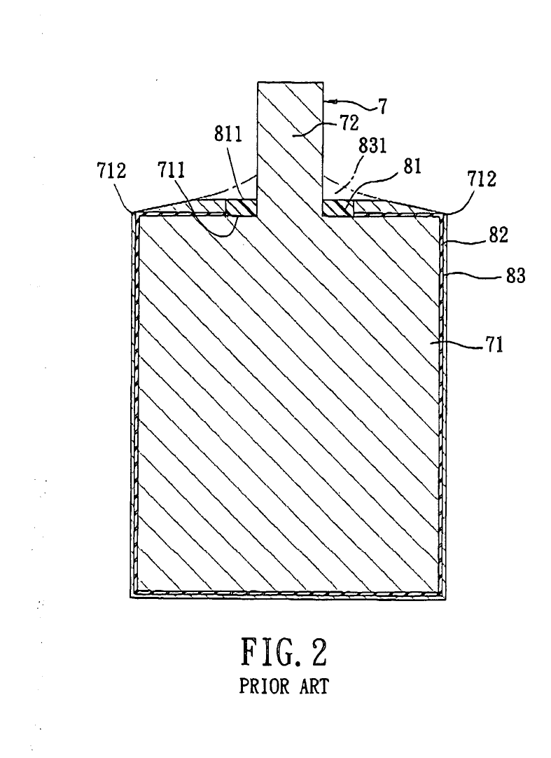

### DETAILED DESCRIPTION OF THE PREFERRED EMBODIMENT

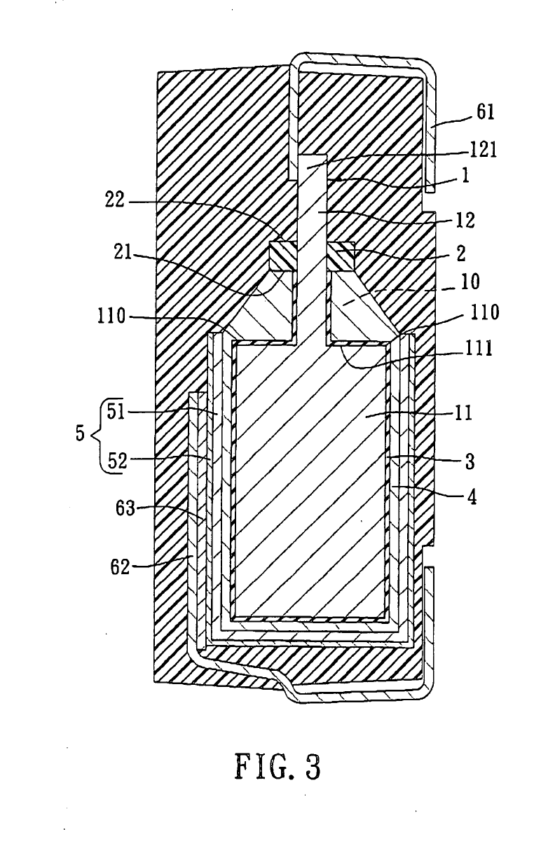

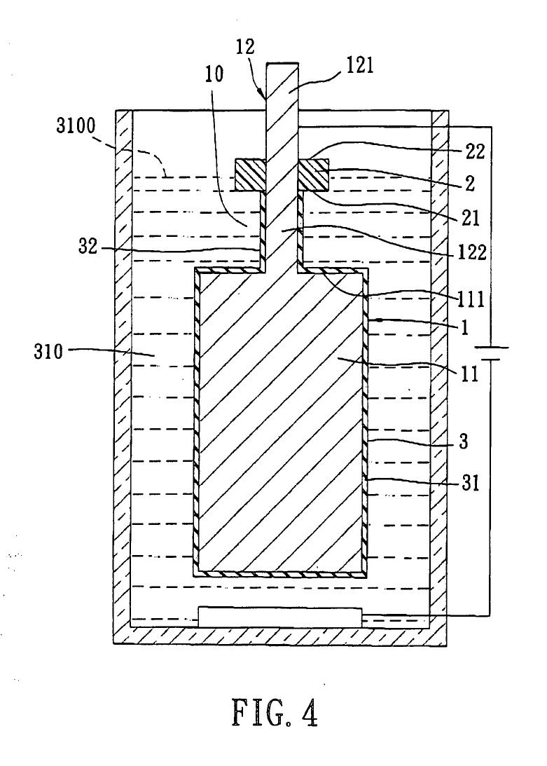

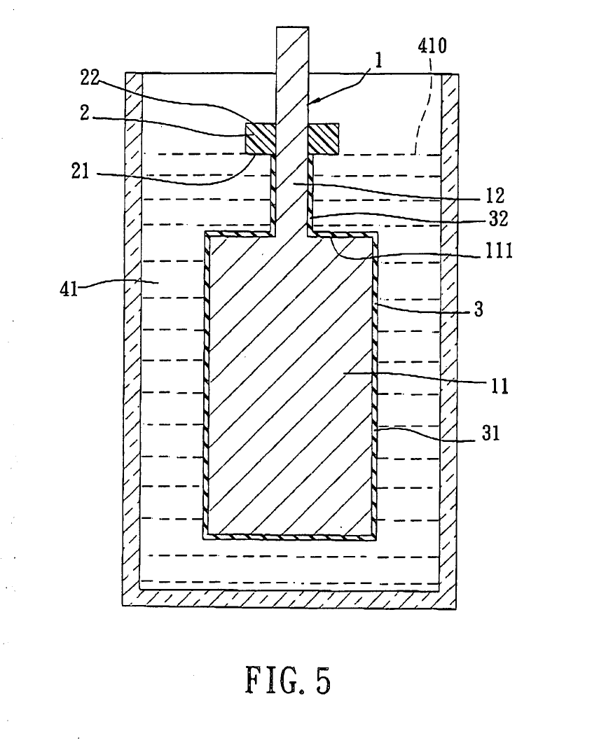

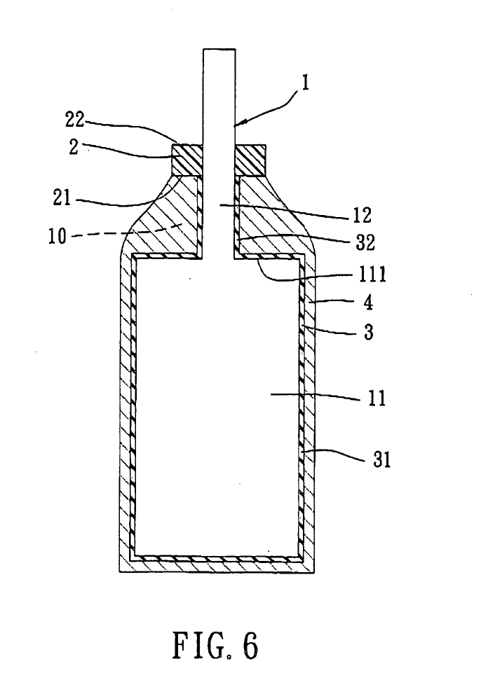

FIG. 3 illustrates the structure of a capacitor formed by the preferred embodiment of a method according to this invention. The method for making the capacitor includes the steps of: (a) forming an anode 1 that has a main body 11 and a lead 12 (see FIG. 4), the main body 11 having an upper end 111, the lead 12 extending outwardly and being reduced in cross-section from the upper end 111 of the main body 11, the anode 1 being formed by sintering techniques using metal powder and a metal rod as the materials for forming the main body 11 and the lead 12 (since formation of the anode 1 is conducted in a conventional manner, a detailed description thereof is dispensed herewith for the sake of brevity); (b) mounting securely an insulator washer 2 of a Teflon® material on the lead 12 (see FIG. 4) such that the insulator washer 2 is spaced apart from the upper end 111 of the main body 11 of the anode 1 by a gap 10 (Note that securing of the insulator washer 2 to the lead 12 of the anode 1 can be conducted by a tool or adhesion using an adhesive), the insulator washer 2 having a lower surface 21 facing the upper end 111 of the main body 11 of the anode 1, and an upper surface 22 opposite to the lower surface 21, and dividing the lead 12 of the anode 1 into an upper end portion 121 that extends upwardly from the upper surface 22 of the insulator washer 2, and a lower end portion 122 that extends downwardly from the lower surface 21 of the insulator washer 2 to the upper end 111 of the main body 11; (c) forming a dielectric layer 3 on an outer surface of the main body 11 and an outer surface of the lower end portion 122 of the lead 12 of the anode 1 (see FIG. 4) such that the dielectric layer 3 has a rain portion 31 covering the cuter surface of the main body 11, and a lead portion 32 covering at least a portion of the outer surface of the lower end portion 122 of the lead 12 of the anode 1; (d) forming a conductive layer 4 on the dielectric layer 3 (see FIGS. 5 and 6) such that the conductive layer 4 5 covers an outer surface of the main portion 31 of the dielectric layer 3 and at least a portion of an outer surface of the lead portion 32 of the dielectric layer 3; and (e) forming a cathode 5 on the conductive layer 4 (see FIG. 3).

The main body 11 and the lead 12 of the anode 1 are preferably made from the same material and are preferably made from a metal selected from the group consisting of tantalum, aluminum, niobium, and titanium. In this embodiment, the main body 11 and the lead 12 of the anode 1 are made from tantalum.

In this embodiment, formation of the dielectric layer 3 in step (c) is conducted by anodizing techniques, in which the anode 1 is placed in a liquid body 310 of an acid electrolyte in an anodizing bath (see FIG. 4) in step (c) in such a manner that the surface 3100 of the liquid body 310 of the acid electrolyte is above the lower surface 21 of the insulator washer 2 and below the upper surface 22 of the insulator washer 2. Suitable acid electrolytes for forming the dielectric layer 3 include phosphoric acid solution and sulfuric acid solution. In this embodiment, the acid electrolyte is sulfuric acid solution.

In this embodiment, formation of the conductive layer 4 in step (d) is conducted by immersing the anode 1 formed with the dielectric layer 3 in a solution 41 of a conductive polymer in a treating bath (see FIG. 5) in such a manner that the surface 410 of the solution 41 of the conductive polymer is substantially flush with the lower surface 21 of the insulator washer 2, removing the anode 1 formed with the dielectric layer 3 and the conductive layer 4 from the treating bath (see FIG. 6), followed by drying a film of the conductive polymer adhered to the dielectric layer 3. Preferably, the conductive polymer is selected from the group consisting of polythiophenes, polyanilines, and polypyrrole. In this embodiment, the conductive polymer is poly-3,4-ethylenedioxythiophene.

In this embodiment, the cathode 5 is formed by coating a graphite layer 51 of a graphite paste on the dielectric layer 3, and a silver layer 52 of a silver paste on the graphite layer 51 in a conventional manner. After formation of the cathode 5, an anode terminal lead 61 is connected to the upper end portion 121 of the lead 12 of the anode 1, and a cathode terminal lead 62 is connected to the cathode 5 through a conductive adhesive 63.

In order to form the capacitor into 2 package, the assembly of the anode 1, the insulator washer 2, the dielectric layer 3, the conductive layer 4, the cathode 5, a portion of the anode terminal lead 61, and a portion of the cathode terminal lead 62 is enclosed by an insulator material using resin molding techniques.

It is noted that the gap 10 formed between the insulator washer 2 and the upper end 111 of the main body 11 of the anode 1 is advantageous in serving as a trapping recess that is capable of retaining the conductive polymer therein when the anode 1 formed with the dielectric layer 3 and the conductive layer 4 is removed from the aforesaid treating bath, thereby providing a sufficient amount of the conductive polymer retained on the upper end 111 of the main body 11 of the anode 1 and preventing corners 110 of the main body 11 of the anode 1 from being exposed from the conductive layer 4 due to downward creeping of the film of the conductive polymer during drying of the conductive polymer as encountered in the prior art.

Moreover, with the formation of the lead portion 32 of the dielectric layer 3 on the lower end portion 122 of the lead 12 of the anode 1 of the capacitor of this invention, the aforesaid undesired excess film, which bridges the lead and the conductive layer and causes short circuit, formed in the aforesaid conventional method of making a capacitor can be avoided. In addition, by spacing the insulator washer 2 apart from the upper end 111 of the main body 11 of the anode 1 by a distance, the immersion depth of the anode 1 in the treating bath can be better observed, which, in turn, facilitates control of the immersion depth of the anode 1 in the treating bath.

While the present invention has been described in connection with what is considered the most practical and preferred embodiment, it is understood that this invention is not limited to the disclosed embodiment but is intended to cover various arrangements included within the spirit and scope of the broadest interpretation and equivalent arrangements.

What is claimed is:

1. A method for making a capacitor, comprising:
(a) forming an anode that has a main body and a lead, the main body having an upper end, the lead extending outwardly and being reduced in cross-section from the upper end of the main body;
(b) mounting securely an insulator washer on the Read such that the insulator washer is spaced apart from the upper end of the main body of the anode, the insulator washer having a lower surface facing the upper end of the main body of the anode, and an upper surface opposite to the lower surface, and dividing the lead of the anode into an upper end portion that extends upwardly from the upper surface of the insulator washer, and a lower end portion that extends downwardly from the lower surface of the insulator washer to the upper end of the main body;
(c) forming a dielectric layer on an outer surface of the main body and an outer surface of the lower end portion of the lead of the anode such What the dielectric layer has a main portion covering the outer surface of the main body, and a lead portion covering at least a portion of the outer surface of the lower end portion of the lead of the anode;
(d) forming a conductive layer on the dielectric layer such that the conductive layer covers an outer surface of the main portion of the dielectric layer and at least a portion of an outer surface of the lead portion of the dielectric layer; and
(e) forming a cathode on the conductive layer.

2. The method of claim 1, wherein formation of the dielectric layer in step (c) is conducted by anodizing techniques.

3. The method of claim 2, wherein the anode is placed in a liquid body of an acid electrolyte in step (c) in such a manner that the surface of the liquid body of the acid electrolyte is above the lower surface of the insulator washer and below the upper surface of the insulator washer.

4. The method of claim 1, wherein the anode is made from a metal selected from the group consisting of tantalum, aluminum, niobium, and titanium.

5. The method of claim 1, wherein formation of the conductive layer in step (d) is conducted by immersing the anode formed is with the dielectric layer in a solution of a conductive polymer, removing the anode formed with the dielectric layer and the conductive layer therefrom, followed by drying a film of the conductive polymer adhered to the dielectric layer.

6. The method of claim 5, wherein the anode formed with the dielectric layer is immersed in the solution of the conductive polymer in such a manner that the surface of the solution of the conductive polymer is substantially flush with the lower surface of the insulator washer.

7. The method of claim 6, wherein the conductive polymer is selected from the group consisting of polythiophenes, polyanilines, and polypyrrole.

8. The method of claim 6, wherein the conductive polymer is poly-3,4-ethylenedioxythiophene.

9. The method of claim 1, wherein the cathode is formed by coating a graphite layer of a graphite paste on the dielectric layer, and a silver layer of a silver paste on the graphite layer.

10. The method of claim 9, further comprising connecting an anode terminal lead to the upper end portion of the lead of the anode, and a cathode terminal lead to the cathode.

11. The method of claim 10, further comprising enclosing an assembly of the anode, the insulator washer, the dielectric layer, the conductive layer, the cathode, a portion of the anode terminal lead, and a portion of the cathode terminal lead using an insulator material.
